(19) United States
(12) Patent Application Publication
(10) Pub. No.: US 2020/0035150 A1
(43) Pub. Date: Jan. 30, 2020

(54) PIXEL ARRAY AND DISPLAY HAVING THE SAME AND ELECTRONIC DEVICE

(71) Applicant: GUANGDONG OPPO MOBILE TELECOMMUNICATIONS CORP., LTD., Dongguan (CN)

(72) Inventor: Yanhao HU, Dongguan (CN)

(73) Assignee: GUANGDONG OPPO MOBILE TELECOMMUNICATIONS CORP., LTD., Dongguan (CN)

(21) Appl. No.: 16/573,370

(22) Filed: Sep. 17, 2019

Related U.S. Application Data
(63) Continuation of application No. 15/982,977, filed on May 17, 2018.

(30) Foreign Application Priority Data
Jun. 12, 2017 (CN) 201710439336.1
Jun. 12, 2017 (CN) 201720681347.6

(51) Int. Cl. G09G 3/3208; G09G 3/20; H01L 27/32

(52) U.S. Cl. CPC G09G 3/3208; G09G 3/2003; G09G 2310/0232; G09G 2300/0452; G09G 2320/0242; H01L 27/3218

(57) ABSTRACT

The present disclosure relates to a pixel array including a plurality of pixel units. Each pixel unit includes a first sub-pixel with first color, a second sub-pixel with second color and a third sub-pixel with third color arranged in a three-by-three pattern with three sub-pixels in each row and three sub-pixels in each column. The first sub-pixels are arranged at a center and four vertexes of each pixel unit, the second sub-pixels and the third sub-pixels are alternately arranged at middle of boundaries of each pixel unit. Adjacent pixel units are arranged to share a common boundary. At a vertex of a pixel unit at an edge of the pixel array, the first sub-pixel is absent, such that the second sub-pixels and the third sub-pixels are alternately arranged on edges of the pixel array. The present disclosure further provides a display and an electronic device.

### CROSS REFERENCE TO RELATED APPLICATIONS

This application is a continuation application of U.S. patent application Ser. No. 15/982,977, filed May 17, 2018, which claims priority to Chinese Patent Application Nos. 201710439336.1 and 201720681347.6, filed Jun. 12, 2017. The entire content of each of the aforementioned applications is incorporated herein by reference.

### FIELD

The present disclosure relates to the display technology field, and more particularly to a pixel array and a display having the same and an electronic device.

### BACKGROUND

In a field of displays, especially in a field of active matrix organic light emitting diode display (AMOLED) technology, it is generally desired to improve a display effect by improving a pixel array.

### SUMMARY

A pixel array includes a plurality of pixel units. Each pixel unit includes a first sub-pixel with first color, a second sub-pixel with second color and a third sub-pixel with third color. The first sub-pixel with first color, the second sub-pixel with second color and the third sub-pixel with third color are arranged in a three-by-three pattern with three sub-pixels in each row and three sub-pixels in each column, the first sub-pixels with first color are arranged at a center and four vertexes of each pixel unit, the second sub-pixels with second color and the third sub-pixels with third color are alternately arranged at middle of boundaries of each pixel unit, adjacent pixel units are arranged to share a common boundary, and at a vertex of a pixel unit at an edge of the pixel array, the first sub-pixel with first color is absent, such that the second sub-pixels with second color and the third sub-pixels with third color are alternately arranged on edges of the pixel array.

A display is provided. The display includes a substrate, an input circuit arranged on the substrate, the above pixel array arranged on the substrate, and a driving circuit arranged on the substrate. The input circuit is configured to receive an image. The pixel array has a plurality of pixel units. Each pixel unit has a first sub-pixel with first color, a second sub-pixel with second color and a third sub-pixel with third color. The first sub-pixel with first color, the second sub-pixel with second color and the third sub-pixel with third color are arranged in a three-by-three pattern with three sub-pixels in each row and three sub-pixels in each column. The first sub-pixels with first color are arranged at a center and four vertexes of each pixel unit, while the second sub-pixels with second color and the third sub-pixels with third color are alternately arranged at middle of boundaries of each pixel unit. Adjacent pixel units are arranged to share a common boundary. At a vertex of a pixel unit at an edge of the pixel array, the first sub-pixel with first color is absent, such that the second sub-pixels with second color and the third sub-pixels with third color are alternately arranged on edges of the pixel array. The driving circuit is arranged on the substrate, and configured to drive the pixel array to display the image.

An electronic device is provided. The electronic device includes a housing, a processor, a memory, a circuit board, a power supply circuit, and a display. The circuit board is enclosed by the housing. The processor and the memory are positioned on the circuit board. The power supply circuit is configured to provide power for respective circuits or components of the electronic device. The display includes the above pixel array.

### BRIEF DESCRIPTION OF THE DRAWINGS

FIG. 1 is a schematic diagram of a pixel array according to an embodiment of the present disclosure.

FIG. 2 is a schematic diagram of a display according to an embodiment of the present disclosure.

FIG. 3 is a schematic diagram of an electronic device according to an embodiment of the present disclosure.

### DETAILED DESCRIPTION

An existing arrangement of the pixel array makes pixel colors imbalanced at edges of the display, and it is difficult to obtain a balanced white at edge regions of the display.

A pixel array and a display having the pixel array provided in an embodiment of the present disclosure may improve a color balance problem at edge regions and may improve a display effect.

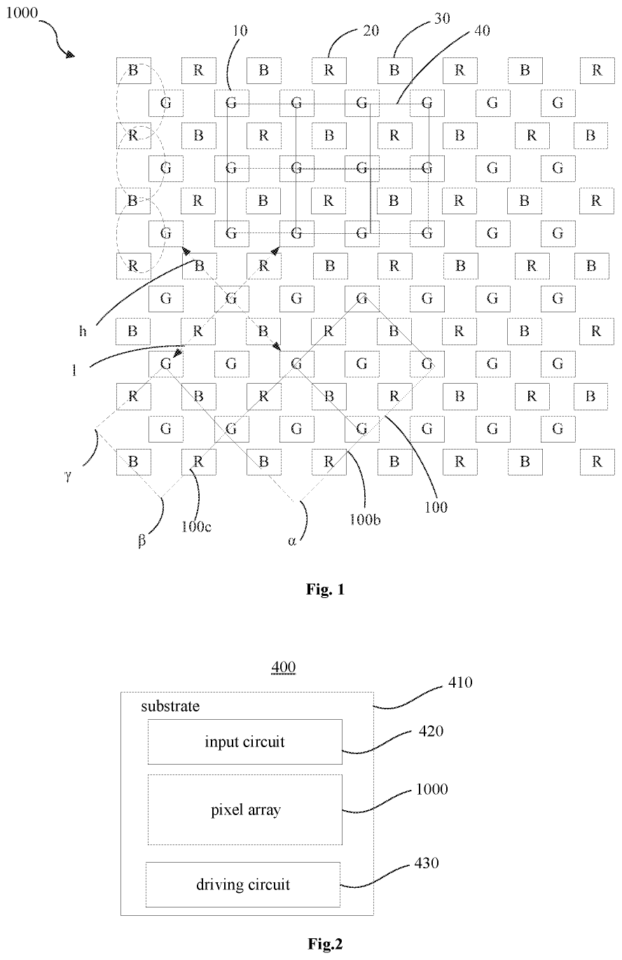

As illustrated in FIG. 1, an embodiment of the present disclosure provides a pixel array 1000. The pixel array 1000 includes a plurality of pixel units 100. Each pixel unit 100 includes a first sub-pixel with first color 10, a second sub-pixel with second color 20 and a third sub-pixel with third color 30.

The first color of the first sub-pixel 10 may be a first one of three-primary colors, the second color of the second sub-pixel 20 may be a second one of the three-primary colors, and the third color of the third sub-pixel 30 may be a third one of the three-primary colors. The three-primary colors refer to red, green and blue which can be merged to make white.

The first sub-pixel with first color 10, the second sub-pixel with second color 20 and the third sub-pixel with third color 30 are arranged in a three-by-three arrangement with three sub-pixels in each row and three sub-pixels in each column. The first sub-pixels with first color 10 are arranged at a center and four vertexes of each pixel unit 100, and the second sub-pixels with second color 20 and the third sub-pixels with third color 30 are alternately arranged at middle of boundaries of each pixel unit. The row and the column may be orthogonal or oblique to each other. Therefore, based on different arrangements, lines connecting respective sub-pixels in each pixel unit 100 may define various geometric patterns, such as rectangles, squares or rhombuses.

Adjacent pixel units 100 are arranged to share a common boundary, for example, the pixel unit 100 share a common boundary with the pixel unit 110b, as illustrated in FIG. 1. For each pixel unit 100 at an edge of the pixel array 1000, the first sub-pixel with first color 10 is absent at a vertex of the pixel unit 100, such that the second sub-pixels with second color 20 and the third sub-pixels with third color 30 are alternately arranged on the edges of the pixel array 1000. For example, as illustrated in FIG. 1, the pixel unit 100b and the pixel unit 100c are arranged at the edge of the pixel array 1000. In the pixel unit 100b, the first sub-pixel with first color 10 at the vertex indicated by α is absent. In the pixel unit 100c, the first sub-pixel with first color 10 at the vertex indicated by β and the first sub-pixel with first color 10 at the vertex indicated by γ are absent. In such pixel units 100 which are located at the edges of the pixel array 1000, the first sub-pixels with first color which are conventionally located at the edges of the pixel array 1000 are absent, such that the second sub-pixels with second color 20 and the third sub-pixels with third color 30 on the boundaries of the pixel units 100 are alternately arranged on the edges of the pixel array 1000. Therefore, at the edges of the pixel array 1000, the first sub-pixels with first color 10, the second sub-pixels with second color 20 and the third sub-pixels with third color 30 are alternately arranged to define triangular regions, as illustrated by broken circles in FIG. 1. Therefore, the first sub-pixels with first color, the second sub-pixels with second color, and the third sub-pixels with third color are distributed evenly at the edges of the pixel array 1000, thereby avoiding a poor display effect due to an imbalance of sub-pixels.

In an embodiment, the first sub-pixel with first color 10 is green. Further, the second color of the second sub-pixel 20 is one of red and blue, while the third color of the third sub-pixel 30 is the other one of red and blue. For example, the second color of the second sub-pixel 20 is red, and the third color of the third sub-pixel 30 is blue. With the above arrangement of the pixel array 1000, when it is desired to display a white color on a display having the above pixel array 1000, no color stripe of a specific color may appear in an edge region of the display, and the white color formed by evenly merging the sub-pixels is displayed.

As illustrated in FIG. 1, in an embodiment, the first sub-pixels with first color 10 are arranged in a matrix and lines connecting the first sub-pixels with first color define a plurality of regular geometric patterns 40. The second sub-pixels with second color 20 and the third sub-pixels with third color 30 are alternately arranged at geometric centers of the regular geometric patterns 40 in each row.

Further, the first sub-pixels with first color 10 are arranged in a matrix and lines connecting the first sub-pixels with first color define a plurality of regular geometric patterns 40. The second sub-pixels with second color 20 and the third sub-pixels with third color 30 are alternately arranged at geometric centers of the regular geometric patterns 40 in each column.

The regular geometric pattern 40 is symmetric, for example, may be a square, a rhombus or a rectangle.

As illustrated in FIG. 1, in each pixel unit 100, three sub-pixels are arranged on each boundary of the pixel unit 100, in which one second sub-pixel with second color 20 or one third sub-pixel with third color 30 is arranged at the middle of each boundary, and two first sub-pixels with first color 10 are arranged at two ends of each boundary, i.e., two vertexes of the pixel unit 100, respectively. The common boundary shared between adjacent pixel units 100 forms a first imaginary line 1 extending in a first direction or a second imaginary line h extending in a second direction. The first imaginary line 1 and the second imaginary line h may be perpendicular or oblique to each other according to geometric patterns defined by lines connecting respective sub-pixels in the pixel unit 100. In an embodiment as illustrated in FIG. 1, the first imaginary line 1 and the second imaginary line h are perpendicular to each other.

On the first imaginary line 1, the first sub-pixels with first color 10 and the second sub-pixels with second color 20 are alternately arranged. On the second imaginary line h, the first sub-pixels with first color 10 and the third sub-pixels with third color 30 are alternately arranged.

Embodiments of the present disclosure further provide a display 400. As illustrated in FIG. 2, the display 400 includes a substrate 410, an input circuit 420 arranged on the substrate 410, the above pixel array 1000 arranged on the substrate 410 and a driving circuit 430 arranged on the substrate 410. The input circuit 420 is configured to receive an image. The driving circuit 430 is configured to drive the pixel array 1000 to display the image. In an embodiment, the display 400 is an organic light emitting diode display. With the display 400 according to embodiments of the present disclosure, a display defect such as a specific color stripe caused by an imbalanced pixel distribution may not appear in edge regions of the display.

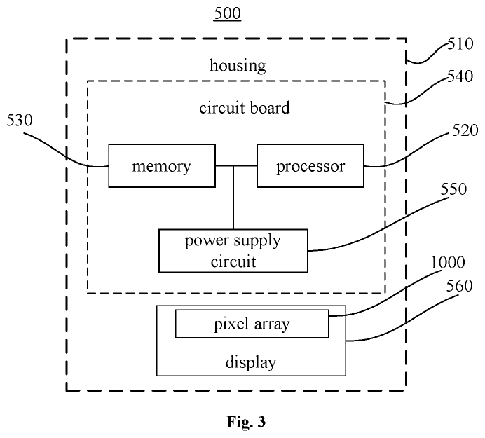

Embodiments of the present disclosure further provide an electronic device 500. As illustrated in FIG. 3, the electronic device 500 includes a housing 510, a processor 520, a memory 530, a circuit board 540, a power supply circuit 550, and a display 560. The display 560 is for example a display having the above pixel array 1000. The circuit board 540 is enclosed by the housing 510. The processor 520 and the memory 530 are positioned on the circuit board 540. The power supply circuit 550 is configured to provide power for respective circuits or components of the electronic device 500. With the electronic device 500, when an image is displayed, a display defect such as a specific color stripe caused by an imbalanced pixel distribution may not appear in edge regions of the display.

Technical features in above described embodiments may be combined arbitrarily. To make the description concise, not all possible combinations of the technical features in the above embodiments are described. However, as long as these combinations of the technical features do not contradict with each other, all of them should be considered within the scope of the specification.

The above embodiments illustrate merely some implementations of the present disclosure, which are described in detail but are not construed to limit the scope of the present disclosure. It should be pointed that, for those skilled in the art, without departing from the principle of the present disclosure, various variants and improvements may be made, which are covered by the protection scope of the present disclosure. Therefore, the protection scope of the present disclosure is according to appended claims.

What is claimed is:

1. A pixel array, comprising a plurality of pixel units, each pixel unit having a first sub-pixel with first color, a second sub-pixel with second color and a third sub-pixel with third color, wherein the first sub-pixel with first color, the second sub-pixel with second color and the third sub-pixel with third color are arranged in a three-by-three pattern with three sub-pixels in each row and three sub-pixels in each column, the first sub-pixels with first color are arranged at a center and four vertexes of each pixel unit, the second sub-pixels with second color and the third sub-pixels with third color are alternately arranged at middle of boundaries of each pixel unit, adjacent pixel units are arranged to share a common boundary, and at a vertex of a pixel unit at an edge of the pixel array, the first sub-pixel with first color is absent, such that the second sub-pixels with second color and the third sub-pixels with third color are alternately arranged on edges of the pixel array; a diagonal line formed by two opposite vertexes of the pixel unit is parallel or perpendicular to the edges of the pixel array; the common boundary shared between adjacent pixel units define a first imaginary line extending in a first direction or a second imaginary line extending in a second direction, the first sub-pixels with first color and the second sub-pixels with second color are alternately arranged along the first imaginary line, and the first sub-pixels with first color and the third sub-pixels with third color are alternately arranged along the second imaginary line; the first direction is perpendicular to the second direction; and the first color of the first sub-pixel is a first one of three-primary colors, the second color of the second sub-pixel is a second one of the three-primary colors, and the third of the third sub-pixel is a third one of the three-primary colors.

2. The pixel array according to claim 1, wherein the first sub-pixels with first color are arranged in a matrix, lines connecting the first sub-pixels with first color define a plurality of regular geometric patterns, and the second sub-pixels with second color and the third sub-pixels with third color are alternately arranged at geometric centers of the regular geometric patterns in each row.

3. The pixel array according to claim 1, wherein the first sub-pixels with first color are arranged in a matrix, lines connecting the first sub-pixels with first color define a plurality of regular geometric patterns, and the second sub-pixels with second color and the third sub-pixels with third color are alternately arranged at geometric centers of the geometric patterns in each column.

4. The pixel array according to claim 1, wherein the first color of the first sub-pixel is green.

5. The pixel array according to claim 4, wherein the second color of the second sub-pixel is one of red and blue and the third color of the third sub-pixel is the other one of red and blue.

6. The pixel array according to claim 1, wherein the second color of the second sub-pixel is red.

7. The pixel array according to claim 1, wherein the third color of the third sub-pixel is blue.

8. A display, comprising:
a substrate;
an input circuit, arranged on the substrate, and configured to receive an image;
a pixel array arranged on the substrate, and having a plurality of pixel units, each pixel unit having a first sub-pixel with first color, a second sub-pixel with second color and a third sub-pixel with third color, wherein the first sub-pixel with first color, the second sub-pixel with second color and the third sub-pixel with third color are arranged in a three-by-three pattern with three sub-pixels in each row and three sub-pixels in each column, the first sub-pixels with first color are arranged at a center and four vertexes of each pixel unit, the second sub-pixels with second color and the third sub-pixels with third color are alternately arranged at middle of boundaries of each pixel unit, adjacent pixel units are arranged to share a common boundary, and at a vertex of a pixel unit at an edge of the pixel array, the first sub-pixel with first color is absent, such that the second sub-pixels with second color and the third sub-pixels with third color are alternately arranged on edges of the pixel array, a diagonal line formed by two opposite vertexes of the pixel unit is parallel or perpendicular to the edges of the pixel array; the common boundary shared between adjacent pixel units define a first imaginary line extending in a first direction or a second imaginary line extending in a second direction, the first sub-pixels with first color and the second sub-pixels with second color are alternately arranged along the first imaginary line, and the first sub-pixels with first color and the third sub-pixels with third color are alternately arranged along the second imaginary line; the first direction is perpendicular to the second direction; and the first color of the first sub-pixel is a first one of three-primary colors, the second color of the second sub-pixel is a second one of the three-primary colors, and the third of the third sub-pixel is a third one of the three-primary colors; and
a driving circuit, arranged on the substrate, and configured to drive the pixel array to display the image.

9. The display according to claim 8, wherein the display is an organic light emitting diode display.

10. The display according to claim 8, wherein the first sub-pixels with first color are arranged in a matrix, lines connecting the first sub-pixels with first color define a plurality of regular geometric patterns, and the second sub-pixels with second color and the third sub-pixels with third color are alternately arranged at geometric centers of the regular geometric patterns in each row.

11. The display according to claim 8, wherein the first sub-pixels with first color are arranged in a matrix, lines connecting the first sub-pixels with first color define a plurality of regular geometric patterns, and the second sub-pixels with second color and the third sub-pixels with third color are alternately arranged at geometric centers of the geometric patterns in each column.

12. The display according to claim 8, wherein the first color of the first sub-pixel is green.

13. The display according to claim 12, wherein the second color of the second sub-pixel is one of red and blue and the third color of the third sub-pixel is the other one of red and blue.

14. The display according to claim 8, wherein the second color of the second sub-pixel is red.

15. The display according to claim 8, wherein the third color of the third sub-pixel is blue.
